(19) United States
(12) Patent Application Publication
(10) Pub. No.: US 2006/0291313 A1
(43) Pub. Date: Dec. 28, 2006

(54) Local sense amplifier and semiconductor memory device having the same

(76) Inventor: Kee-Won Kwon, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/375,808

(22) Filed: Mar. 14, 2006

(30) Foreign Application Priority Data
Jun. 17, 2005 (KR) 2005-52509

(51) Int. Cl. G11C 7/02

(52) U.S. Cl. 365/207

(57) ABSTRACT

A sense amplifier including a pair of differential transistors configured to amplify a differential signal applied to a pair of I/O lines, each transistor having a terminal, a current supplying circuit configured to supply a current to the differential transistors in response to an enable signal, and a coupling element configured to electrically connect or disconnect the terminals of the differential transistors in response to the enable signal.

### CROSS-REFERENCE TO RELATED APPLICATIONS

This application claims the benefit under 35 U.S.C. §119(a) of Korean Patent Application No. 2005-0052509 filed on Jun. 17, 2005, the contents of which are herein incorporated by reference in their entirety.

### BACKGROUND OF THE INVENTION

1. Field of the Invention

This disclosure relates to a semiconductor memory device and, more particularly, relates to a local sense amplifier having redundant circuitry for a semiconductor memory device.

2. Description of the Related Art

FIG. 1 is a circuit diagram illustrating a conventional DRAM (Dynamic Random Access Memory) device. Referring to FIG. 1, the DRAM device includes a memory cell 10 for storing a data, a latch 20 for latching voltages of a bit line pair BL and BLB, a bit line sense amplifier 30 for amplifying the voltages of the bit line pair BL and BLB, and a local sense amplifier 40 for amplifying voltages of local I/O (input/output) line pair LIO and LIOB, which are provided to global I/O line pair GIO and GIOB.

A semiconductor memory device may have multiple memory cells 10, latches 20, bit line sense amplifiers 30, and local sense amplifiers 40. The semiconductor memory device can be stably operated by using the bit line sense amplifiers 30 and the local sense amplifiers 40 in spite of mismatches between data paths having large loads and charge sources having small drive capabilities.

FIG. 2 is a circuit diagram illustrating the local sense amplifier for the DRAM device in FIG. 1. The local sense amplifier 40 performs amplification under a control of control signals PWBLK, PWBBLK, and an enable signal EN, and overcomes loading mismatches between the global I/O line pair GIO and GIOB, and the local I/O line pair LIO and LIOB, so that the memory device operates stably.

When there is just one bad memory cell among a myriad of memory cells, a semiconductor memory device may function improperly, and be classified as a defective product. A modem semiconductor memory device has redundant memory cells with which the defective memory cells are replaced, in order to repair the defective memory device, thereby converting the defective memory device into a non-defective memory device. The defective memory cells are substituted with the redundant memory cells by either rows or columns. When a defective memory cell is found in a test, followed by a wafer process, an address of the defective memory cell is repaired with an address of the redundant memory cell. As a result, an address corresponding to an I/O line of a defective memory cell is rerouted to a redundant I/O line instead of the defective I/O line.

FIG. 3 is a circuit diagram illustrating a redundant local sense amplifier 130 and a main local sense amplifier 110 in FIG. 2. Referring to FIG. 3, in a read operation, the control signal PWBLK and the enable signal EN1 are activated and the control signal PWBBLK is deactivated. Then, signals on the local I/O line pair LIO and LIOB are amplified by the local sense amplifier 110 to be provided to the global I/O line pair GIO and GIOB. In a write operation, the control signal PWBLK is deactivated and the control signal PWBBLK is activated. Signals on the global I/O line signals GIO and GIOB are provided to the local I/O line pair LIO and LIOB.

When the defective memory cells in the DRAM device are accessed, the redundant circuitry is activated and the redundant local sense amplifier 130 is used instead of the local sense amplifier 110. The local sense amplifier 110 is disabled by the deactivation of the enable signal EN1 and the redundant local sense amplifier 130 is enabled by activation of an enable signal EN3. In the read operation, the control signal PWBLK and the enable signal EN3 are activated and the control signal PWBBLK is deactivated. Signals on a redundant local I/O line pair RLIO and RLIOB are amplified by the redundant local sense amplifier 130 to be provided to a redundant global I/O line pair RGIO and RGIOB. In the write operation, the control signal PWBLK is deactivated and the control signal PWBBLK and the enable signal EN3 are activated. Signals on the redundant global I/O line pair RGIO and RGIOB are provided to the redundant local I/O line pair RLIO and RLIOB.

In the read operation with the redundant local sense amplifier 130, voltage levels of the redundant global I/O line pair RGIO and RGIOB may be equalized by an undesired current loop formed in the local sense amplifier 110. That is, though an NMOS transistor 117 is disabled by deactivating the enable signal EN1, the redundant global I/O line pair RGIO and RGIOB may be equalized by the undesired current loop that includes a node PA, a node PB, an NMOS transistor 113, an NMOS transistor 115, an NMOS transistor 116, an NMOS transistor 114, a node PC and a node PD. As a result, the redundant global I/O line pair RGIO and RGIOB may have unintentionally weak output signals due to the equalization.

### SUMMARY OF THE INVENTION

An embodiment includes a sense amplifier including a pair of differential transistors configured to amplify a differential signal applied to a pair of I/O lines, each transistor having a terminal, a current supplying circuit configured to supply a current to the differential transistors in response to an enable signal, and a coupling element configured to electrically connect or disconnect the terminals of the differential transistors in response to the enable signal.

Another embodiment includes a semiconductor memory device including a main circuit including a pair of local I/O lines, a pair of global I/O lines and a local sense amplifier coupled between the local I/O lines and the global I/O lines, and a redundant circuit including a pair of redundant local I/O lines, a pair of redundant global I/O lines electrically coupled to the global I/O lines, and a redundant local sense amplifier coupled between the redundant local I/O lines and the redundant global I/O lines. At least one of the local sense amplifier and the redundant local sense amplifier includes a pair of differential transistors configured to amplify a differential signal applied to the associated local I/O lines and to provide the amplified differential signal to the associated global I/O lines, each transistor having a terminal, a current supplying circuit configured to supply a current to the differential transistors in response to an associated enable signal, and a coupling element configured to electrically connect or disconnect the terminals of the differential transistors in response to the associated enable signal.

### BRIEF DESCRIPTION OF THE DRAWINGS

The above and other features and advantages of the invention will become more apparent by describing in detail embodiments thereof with reference to the accompanying drawings, in which:

FIG. 1 is a circuit diagram illustrating a conventional DRAM device.

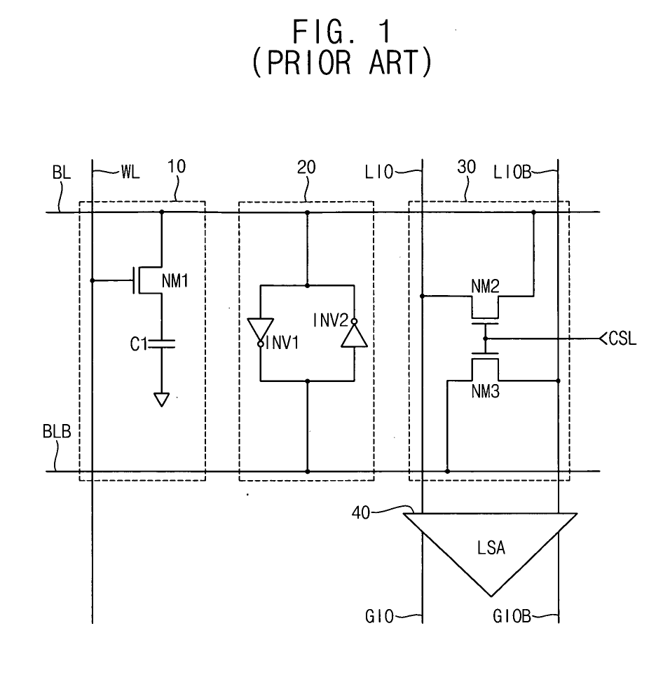

FIG. 2 is a circuit diagram illustrating the local sense amplifier for the DRAM device in FIG. 1.

FIG. 3 is a circuit diagram illustrating a redundant local sense amplifier and a main local sense amplifier as in FIG. 2.

FIG. 4 is a circuit diagram illustrating a local sense amplifier according to an embodiment.

FIG. 5 is a circuit diagram illustrating an example implementation of a current supplying unit for the local sense amplifier in FIG. 4.

FIG. 6 is a circuit diagram illustrating an example implementation of a redundant local sense amplifier and the local sense amplifier in FIG. 4.

FIGS. 7A to 7C are graphs showing waveforms of voltage signals of the circuits in FIG. 3 and FIG. 6.

FIG. 8 is a schematic diagram illustrating a DRAM with the local sense amplifier in FIG.6.

### DESCRIPTION OF EMBODIMENTS

Embodiments are described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

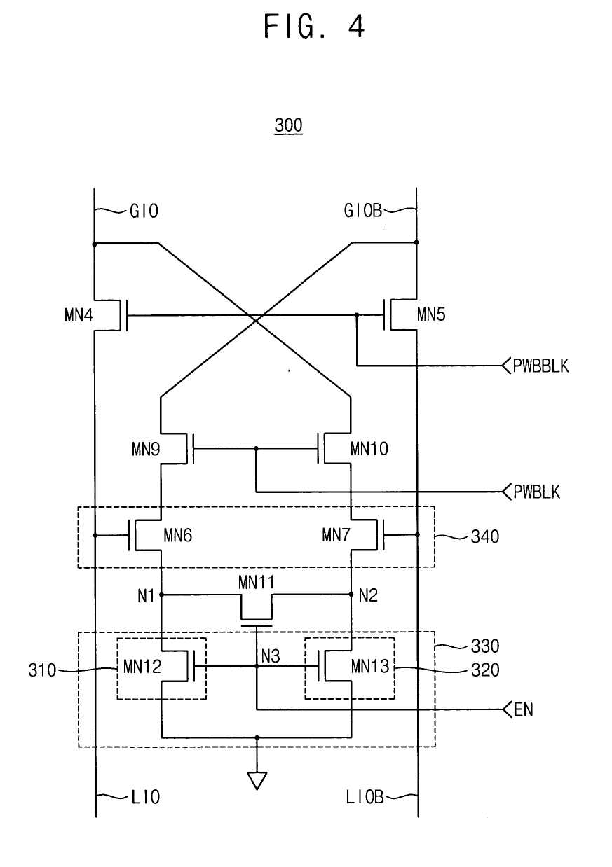

FIG. 4 is a circuit diagram illustrating a local sense amplifier according to an embodiment. Referring to FIG. 4, the local sense amplifier 300 includes a differential transistor pair 340 having NMOS transistors MN6 and MN7, a current supplying unit 330 having NMOS transistors MN12 and MN13, and an NMOS coupling transistor MN1 that performs a coupling function. The differential transistor pair 340 amplifies a differential signal applied to the local I/O line pair LIO and LIOB. The current supplying unit 330 supplies electric current to the differential transistor pair 340 in response to an enable signal EN. The coupling transistor MN11 electrically couples a node N1 and another node N2 to have substantially the same voltage levels in response to the enable signal EN.

In the current supplying unit 330, the NMOS transistor MN12 and the NMOS transistor MN13 respectively supply current to the node N1 and to the node N2 in response to the enable signal EN.

The local sense amplifier 300 in FIG. 4 also includes NMOS transistors MN9 and MN10. The NMOS transistor MN9 provides a drain current of an NMOS transistor MN6 to a first line GIOB of the global I/O line pair in response to a first control signal PWBLK. The NMOS transistor MN10 provides a drain current of an NMOS transistor MN7 to a second line GIO of the global I/O line pair in response to the first control signal PWBLK.

The local sense amplifier 300 further includes NMOS transistors MN4 and MN5. The NMOS transistor MN4 provides a signal of the second line GIO of the global I/O line pair to a first line LIO of the local I/O line pair in response to a second control signal PWBBLK. The NMOS transistor MN5 provides a signal of the first line GIOB of the global I/O line pair to a second line LIOB of the local I/O line pair in response to the second control signal PWBBLK.

Operations of the local sense amplifier 300 in FIG. 4 are described in detail below.

The enable signal EN is a control signal to enable or disable the local sense amplifier 300. The control signal PWBLK is activated at a read operation and a control signal PWBBLK is activated at the write operation.

In the read operation, the enable signal EN and the control signal PWBLK are activated and the control signal PWBBLK is deactivated. The signals on the local I/O line pair LIO and LIOB, output from bit line sense amplifier (not shown), are applied to the differential transistor pair MN6 and MN7. The signals on the local I/O line pair LIO and LIOB are amplified by the differential transistor pair MN6 and MN7, and the amplified signals are applied to the global I/O line pair GIO and GIOB through the NMOS transistors MN9 and MN10, when the control signal PWBLK is activated.

In the write operation, the control signal PWBBLK is activated and the control signal PWBLK is deactivated. The enable signal may be deactivated. With activation of the control signal PWBBLK, the NMOS transistors MN4 and MN5 are enabled and the signals on the global I/O line pair GIO and GIOB are provided to the local I/O line pair LIO and LIOB.

When the enable signal EN is deactivated, the NMOS transistor MN11 is turned off. When the enable signal EN is activated, the NMOS transistor MN11 is turned on, and the nodes N1 and N2 have substantially the same voltage levels.

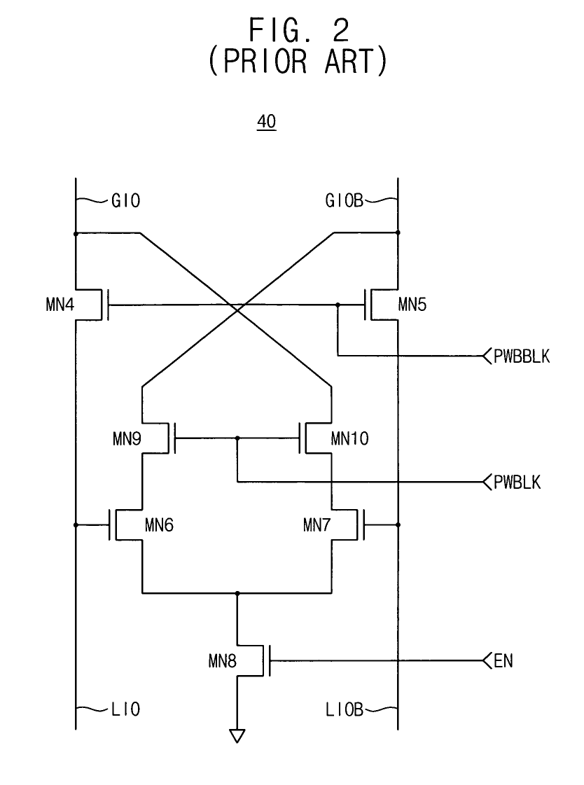

The local sense amplifier 300, according to the embodiment in FIG. 4, electrically disconnects the nodes N1 and N2 when the local sense amplifier 300 is disabled with deactivation of the enable signal EN. Therefore, the local sense amplifier 300 has no undesired current loop of the conventional local sense amplifier 40 in FIG. 2.

The local sense amplifier 300, according to the embodiment in FIG. 4, has the current supplying unit 330 that includes two NMOS transistors MN12 and MN13, and thus is different from the local sense amplifier 40 in FIG. 2. The local sense amplifier 300 in FIG. 4 further includes the NMOS transistor MN1 coupling the nodes N1 and N2 to simultaneously enable the NMOS transistors MN12 and MN13, when the local sense amplifier 300 is enabled by activation of the enable signal EN. Therefore, amplification gain of the local sense amplifier 300 is substantially the same as a gain of the conventional local sense amplifier 40.

The NMOS transistor MN11 of the local sense amplifier 300 in FIG. 4 electrically couples the nodes N1 and N2 to have substantially the same voltage levels, and may reduce offsets caused by mismatches of the NMOS transistor MN12 and MN13.

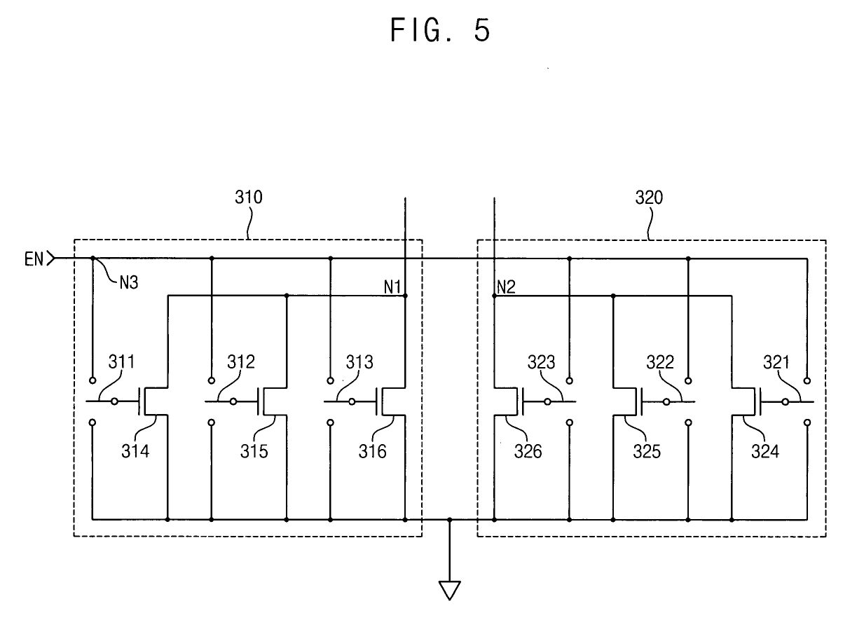

FIG. 5 is a circuit diagram illustrating an example implementation of a current supplying unit for the local sense amplifier in FIG. 4. Referring to FIG. 5, an NMOS transistor set 310, representing the transistor MN12 in FIG. 4, includes NMOS transistors 314 to 316, and switches 311 to 313. An NMOS transistor set 320, representing the transistor MN13 in FIG. 4, includes NMOS transistors 324 to 326, and switches 321 to 323.

According to other embodiments, the NMOS transistor sets 310 and 320 may include any number of transistors with switches respectively coupled to the transistors, even though the NMOS transistor sets 310 and 320 in FIG. 4 are each implemented by three NMOS transistors configured in parallel and three switches coupled to each of the three NMOS transistors.

The NMOS transistors 314 to 316 and 324 to 326 of the NMOS transistor sets 310 and 320 are respectively connected to the enable signal EN or ground by the switches 311 to 313 and 321 to 323.

The NMOS transistors 314 to 316 and 324 to 326 of the NMOS transistor sets 310 and 320 may have a configuration symmetrical to each other. For example, the NMOS transistors 314, 315 and 316 respectively may have substantially the same size as the NMOS transistors 324, 325 and 326. The transistors 314 to 316 in the NMOS transistor set 310 may have substantially the same size with each other or may have different sizes with each other. The transistors 324 to 326 in the NMOS transistor set 320 also may have substantially the same size with each other or may have different sizes with each other.

Operations of the circuit are described below in FIG. 5.

First, the NMOS transistors 314 to 316 in the NMOS transistor set 310 and the NMOS transistors 324 to 326 in the NMOS transistor set 320 may be of substantially the same size. When, with activation of the enable signal EN, gates of the NMOS transistors 314 and 324 are connected to a node N3 by the switches 311 and 321, and gates of the transistors 315, 316, 325, and 326 are grounded, the current flowing through the NMOS transistor set 310 is substantially the same as a current flowing through the NMOS transistor 314 and the current flowing through the NMOS transistor set 320 is substantially the same as a current flowing through the NMOS transistor 324.

When, with activation of the enable signal EN, gates of the NMOS transistors 314, 315, 324 and 325 are connected to the node N3 by the switches 311, 312, 321 and 322, and the gates of the transistors 316 and 326 are grounded, the current flowing through the NMOS transistor set 310 is substantially the same as a sum of currents flowing through the NMOS transistors 314 and 315, and the current flowing through the NMOS transistor set 320 is substantially the same as a sum of currents flowing through the NMOS transistors 324 and 325.

When, with activation of the enable signal EN, gates of the NMOS transistors 314 to 316 and 324 to 326 are connected to the node N3 by the switches 311 to 313 and 321 to 323, the current flowing through the NMOS transistor set 310 is substantially the same as a sum of currents flowing through the NMOS transistors 314 to 316, and the current flowing through the NMOS transistor set 320 is substantially the same as a sum of currents flowing through the NMOS transistors 324 to 326.

Therefore, when all NMOS transistors 314 to 316 and 324 to 326 of the NMOS transistor sets 310 and 320 are of substantially the same size, the current supplied to the differential transistor pair MN6 and MN7 in FIG. 4 increases in proportion to the number of the NMOS transistors that are turned on with the enable signal EN. That is, when two NMOS transistors are turned on, the differential transistor pair MN6 and MN7 in FIG. 4 is provided with a current two times as large as that when one NMOS transistor is turned on. With three NMOS transistors turned on, the current would be three times as large as that when one NMOS transistor is turned on.

According to other embodiments, the NMOS transistors 314 to 316 and 324 to 326 in the NMOS transistor sets 310 and 320 may have different sizes. For example, the NMOS transistor 315 may be twice as large as the NMOS transistor 314, and the NMOS transistor 316 may be four times as large as the NMOS transistor 314. The NMOS transistor 325 may be two times as large as the NMOS transistor 324, and the NMOS transistor 326 is four times as large as the NMOS transistor 324. Thus, the current supplied to the differential transistor pair may be adjustable as a binary code form. For example, when the NMOS transistors 314 and 324 supply 1 unit of current, the NMOS transistors 315 and 325 supply 2 units of current and the NMOS transistors 316 and 326 supply 4 units of current. The amount of current depends on how many and which transistors are turned on.

In FIG. 5, the switches 311 to 313 and 321 to 323 may be connected to the node N1 or grounded by a fusing process after performing test items in the wafer test step of the semiconductor processing.

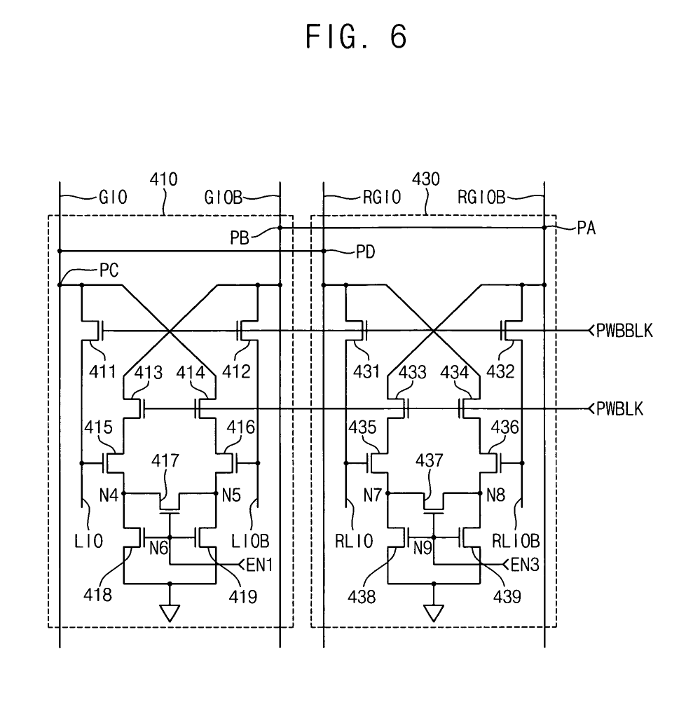

FIG. 6 is a circuit diagram illustrating an example implementation of a redundant local sense amplifier and the local sense amplifier in FIG. 4. Referring to FIG. 6, a local sense amplifier 410 and a redundant local sense amplifier 430 have substantially the same structure.

The local sense amplifier 410 includes a local I/O line pair LIO and LIOB, a global I/O line pair GIO and GIOB, and NMOS transistors 411 to 419. The NMOS transistor 415 has a gate coupled to the local I/O line LIO and a source coupled to a node N4. The NMOS transistor 416 has a gate coupled to the local I/O line LIOB and a source coupled to a node N5. The NMOS transistor 418 has a gate responsive to an enable signal EN1, a source coupled to ground and a drain coupled to the node N4. The NMOS transistor 419 has a gate responsive to the enable signal EN1, a source coupled to ground and a drain coupled to the node N5. The NMOS transistor 417 acts as a coupling element for coupling the nodes N4 and N5 so that the nodes N4 and N5 have substantially the same voltage levels, in response to the enable signal EN1.

The NMOS transistor 414 provides an output current of the NMOS transistor 416 to the global I/O line GIO in response to a control signal PWBLK. The NMOS transistor 413 provides an output current of the NMOS transistor 415 to the global I/O line GIOB in response to the control signal PWBLK. The NMOS transistor 411 provides a signal on the global I/O line GIO to the local I/O line LIO in response to a control signal PWBBLK. The NMOS transistor 412 provides a signal on the global I/O line GIOB to the local I/O line LIOB in response to the control signal PWBBLK.

The redundant local sense amplifier 430 includes a redundant local I/O line pair RLIO and RLIOB, a redundant global I/O line pair RGIO and RGIOB, and NMOS transistors 431 to 439. The NMOS transistor 435 has a gate coupled to the redundant local I/O line RLIO and a source coupled to a node N7. The NMOS transistor 436 has a gate coupled to the redundant local I/O line RLIOB and a source coupled to a node N8. The NMOS transistor 438 has a gate responsive to an enable signal EN3, a source coupled to ground and a drain coupled to the node N7. The NMOS transistor 439 has a gate responsive to the enable signal EN3, a source coupled to ground and a drain coupled to the node N8. The NMOS transistor 437 acts as a coupling element for coupling the nodes N7 and N8 to cause the nodes N7 and N8 to have substantially the same voltage levels, in response to the enable signal EN3. The gates of the NMOS transistors 437, 438 and 439 are commonly coupled to the node N9 to receive the enable signal EN3.

The NMOS transistor 434 provides an output current of the NMOS transistor 436 to the redundant global I/O line RGIO in response to the control signal PWBLK. The NMOS transistor 433 provides an output current of the NMOS transistor 435 to the redundant global I/O line RGIOB in response to the control signal PWBLK. The NMOS transistor 431 provides a signal on the redundant global I/O line RGIO to the redundant local I/O line RLIO in response to the control signal PWBBLK. The NMOS transistor 432 provides a signal on the redundant global I/O line RGIOB to the redundant local I/O line RLIOB in response to the control signal PWBBLK.

In FIG. 6, the global I/O line GIO is electrically coupled to the redundant global I/O line RGIO, and the global I/O line GIOB is electrically coupled to the redundant global I/O line RGIOB.

Operations of the circuit illustrated in FIG. 6 are described below.

When the defective memory cells in the DRAM device are accessed, the redundant circuitry is activated and the redundant local sense amplifier 430 is used instead of the local sense amplifier 410 in FIG. 6. The local sense amplifier 410 becomes disabled by deactivation of the enable signal EN1 and the redundant local sense amplifier 430 becomes enabled by activation of the enable signal EN3. In a read operation, the control signal PWBLK and the enable signal EN3 are activated and the control signal PWBBLK is deactivated. Signals on the redundant local I/O line pair RLIO and RLIOB are amplified by the redundant local sense amplifier 430 to be provided to the redundant global I/O line pair RGIO and RGIOB. In a write operation, the control signal PWBLK is deactivated and the control signal PWBBLK and the enable signal EN3 are activated. Signals on the redundant global I/O line pair RGIO and RGIOB are provided to the redundant local I/O line pair RLIO and RLIOB.

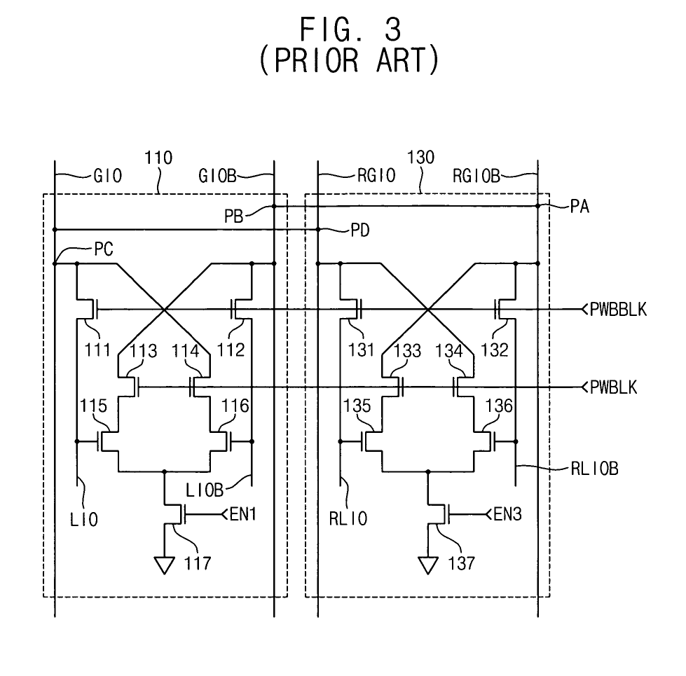

In the read operation, the redundant local sense amplifier 130 in FIG. 3 has an undesired current loop formed in the local sense amplifier 110, so that voltage levels of the redundant global I/O line pair RGIO and RGIOB may be equalized by the undesired current loop. A local sense amplifier, according to the embodiment in FIG. 6, does not have such an undesired current loop. When the enable signal EN1 is deactivated turning the NMOS transistors 418 and 419 off, the NMOS transistor 417 acting as a coupling element is also turned off. The current loop is broken and voltage levels of the redundant global I/O line pair RGIO and RGIOB are not equalized.

The local sense amplifier 300 in FIG. 4 has the coupling element including the NMOS transistor MN11 so as to electrically couple the nodes N1 and N2 to cause the nodes N1 and N2 to have substantially the same voltage levels in response to the enable signal EN. When the enable signal EN1 is deactivated to disable the local sense amplifier 410 and the enable signal EN3 is activated to enable the redundant local sense amplifier 430, the redundant global I/O line pair RGIO and RGIOB in a DRAM device with the circuit according to the embodiment in FIG. 4 are not equalized. The signals on the redundant local I/O line pair RLIO and RLIOB are provided to the redundant global I/O line pair RGIO and RGIOB intact.

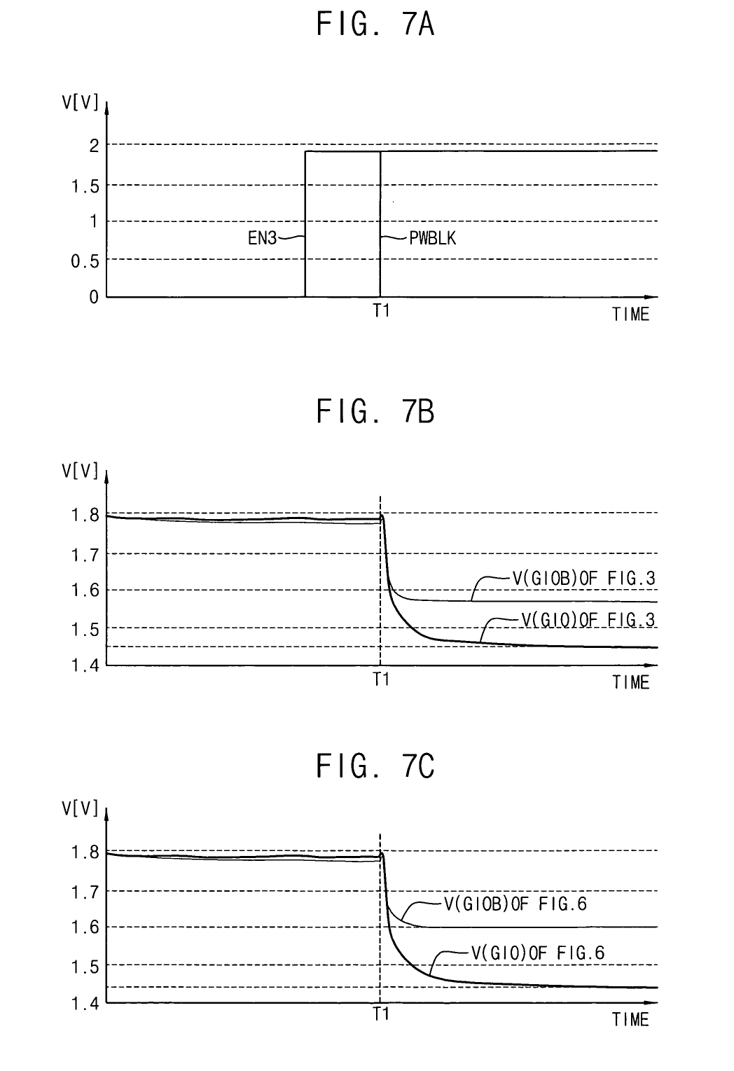

FIGS. 7A to 7C are graphs showing waveforms of voltage signals of the circuits in FIG. 3 and FIG. 6.

As shown in FIG. 7A, after the enable signal EN3 is activated, the control signal PWBLK is activated. FIG. 7B shows voltage waveforms V(GIO) and V(GIOB) from the global I/O lines of the conventional DRAM device in FIG. 3. Similarly, FIG. 7C shows voltage waveforms V(GIO) and V(GIOB) from the global I/O lines of the DRAM device in FIG. 6.

Referring to FIGS. 7B and 7C, after the control signal PWBLK is activated at time TI, a voltage difference, V(GIO)-V(GIOB), of the global I/O line pair of the DRAM device according to the embodiments in FIG. 6, is larger than that of the global I/O line pair of the conventional DRAM device in FIG. 3. The reason is that the DRAM device according to the embodiments includes the coupling element including the NMOS transistor (MN 1I in FIG. 4). As a result, no undesired current loop is formed in the local sense amplifier, and the redundant global I/O line pair RGIO and RGIOB in FIG. 6 is not equalized, when the local sense amplifier 410 is turned off and the redundant local sense amplifier 430 is activated.

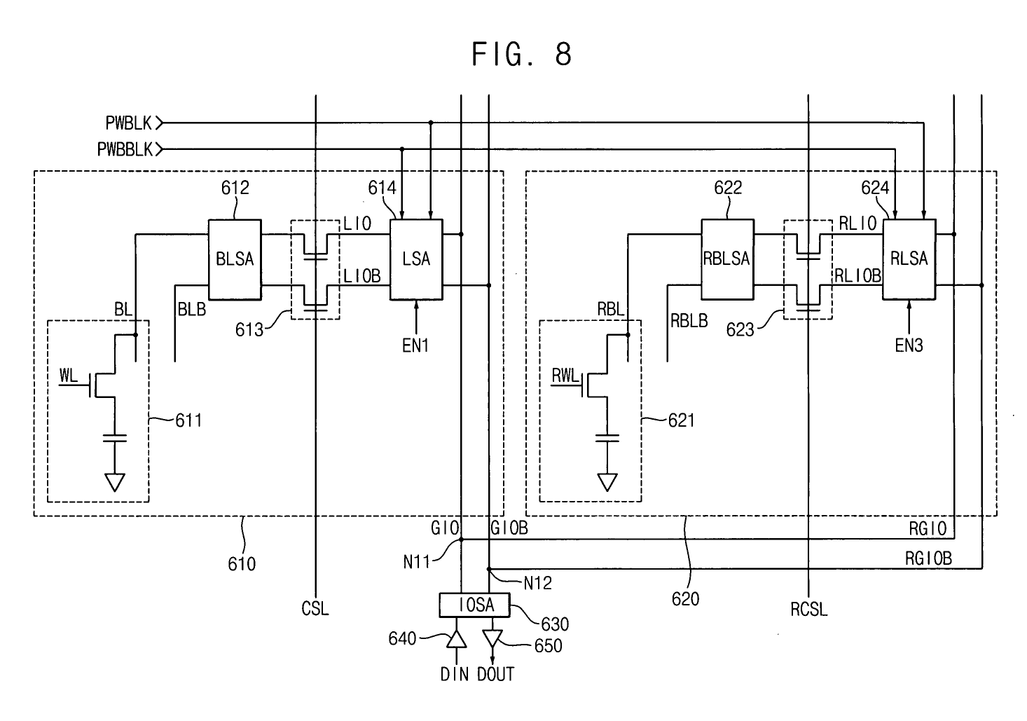

FIG. 8 is a schematic diagram illustrating a DRAM device with the local sense amplifier of FIG. 6. Referring to FIG. 8, the DRAM device includes a main circuit 610, a redundant circuit 620 and an I/O sense amplifier (IOSA) 630. The DRAM device further includes an input buffer 640 for receiving and buffering an input data DIN and an output buffer 650 for receiving and buffering an output signal from the I/O sense amplifier 630 to output an output data DOUT.

The main circuit 610 includes a memory cell 611, a bit line sense amplifier (BLSA) 612, a column selection circuit 613 and a local sense amplifier (LSA) 614. The redundant circuit 620 includes a redundant memory cell 621, a redundant bit line sense amplifier (RBLSA) 622, a redundant column select circuit 623 and a redundant local sense amplifier (RLSA) 624.

Operations of the DRAM device in FIG. 8 are described as follows. Firstly, the operation of the main circuit 610 in a read operation of the DRAM device is described.

In the read operation, a row address is applied and data in the memory cell 611 is outputted to a bit line pair BL and BLB. Signals on the bit line pair BL and BLB are amplified by the bit line sense amplifier 612, whose output signals are provided to the local I/O line pair LIO and LIOB through the column selection circuit 613, when a column selection signal CSL is activated. The local sense amplifier 614 provides signals of the local I/O line pair LIO and LIOB to the global I/O line pair GIO and GIOB in response to the control signals EN1, PWBLK and PWBBLK. Signals on the global I/O line pair GIO and GIOB are amplified by the I/O sense amplifier 630 to be output through the output buffer 650.

Next, the operation of the main circuit 610 in a write operation of the DRAM device is described as follows.

In the write operation, the input data DIN is buffered by the input buffer 640 and is amplified by the I/O sense amplifier 630 to be provided to the global I/O line pair GIO and GIOB. Signals on the global I/O line pair GIO and GIOB are provided to the local I/O line pair LIO and LIOB through the local sense amplifier 614. Signals on the local I/O line pair LIO and LIOB are provided to the bit line pair BL and BLB through the column selection circuit 613 and the bit line sense amplifier 612, when the column selection signal CSL is activated. With activation of a word line WL, the signals on the bit line pair BL and BLB are stored into the memory cell 611.

Operations of the redundant circuit 620 in a read operation are described below. The redundant circuit 620 may be substituted for the main circuit 610 when the main circuit 610 with the memory cell 611 is defective.

When a defect occurs in the main circuit 610 with the memory cell 611, a word line enable signal is applied to a redundant word line RWL in the redundant circuit 620 instead of the word line WL. Data in a redundant memory cell 621 is output to a redundant bit line pair RBL and RBLB. Signals on the redundant bit line pair RBL and RBLB are amplified by the redundant bit line sense amplifier 622, whose output signals are provided to the redundant local I/O line pair RLIO and RLIOB through the redundant column selection circuit 623, when a redundant column selection signal RCSL is activated. The redundant local sense amplifier 624 provides signals of the redundant local I/O line pair RLIO and RLIOB to the redundant global I/O line pair RGIO and RGIOB in response to the control signals EN3, PWBLK and PWBBLK. Signals on the redundant global I/O line pair RGIO and RGIOB are amplified by the I/O sense amplifier 630 to be output through the output buffer 650. The redundant global I/O line pair RGIO and RGIOB are respectively electrically coupled to the global I/O line pair GIO and GIOB at nodes N11 and N12.

In a write operation of the DRAM device, the operation of the redundant circuit is as follows. The input data DIN is buffered by the input buffer 640 and is amplified by the I/O sense amplifier 630 to be provided to the redundant global I/O line pair RGIO and RGIOB. Signals on the redundant global I/O line pair RGIO and RGIOB are provided to the redundant local I/O line pair RLIO and RLIOB through the redundant local sense amplifier 624. Signals on the redundant local I/O line pair RLIO and RLIOB are provided to the redundant bit line pair RBL and RBLB through the redundant column selection circuit 623 and the redundant bit line sense amplifier 622, when the redundant column selection signal RCSL is activated. With the activation of a redundant word line RWL, the signals on the redundant bit line pair RBL and RBLB are stored into the redundant memory cell 621.

When a defect occurs in the main circuit 610 with the memory cell 611, the semiconductor memory device according to the embodiments in FIG. 8 deactivates the enable signal EN1 to turn off the local sense amplifier 614 in the main memory circuit 610 and activates the enable signal EN3 to turn on the redundant local sense amplifier 624 in the redundant circuit 620, when the defective memory cell is accessed. In the semiconductor memory device having the conventional sense amplifier 40, an undesired current loop is formed inside the local sense amplifier when the local sense amplifier is turned off and the redundant local sense amplifier is used.

The semiconductor memory device having the sense amplifier 300 according to the embodiment in FIG. 4 has no undesired current loop formed inside the local sense amplifier when the local sense amplifier in the main circuit is turned off and the redundant local sense amplifier in the redundant circuit is used. The reason is that the local sense amplifier 300 in FIG. 4 includes the coupling element having the NMOS transistor MN11, which electrically couples the node N1 and the node N2 causing the nodes N1 and N2 to have potential levels substantially equal to each other, in response to the enable signal EN.

As described above, the local sense amplifier according to an embodiment includes a coupling element between low potential terminals of the differential transistor pair so as to prevent an undesired current loop from forming in the local sense amplifier while the local sense amplifier is disabled. The local sense amplifier according to an embodiment may adjust amplification gain by controlling the amount of current supplied to the differential transistor pair in the local sense amplifier.

A semiconductor memory device may have main circuits and redundant circuits to substitute for the main circuits. When a main circuit is defective, the local sense amplifier in the defective main circuit is disabled and the redundant local sense amplifier in the redundant circuit is enabled. A semiconductor memory device, which has a local sense amplifier and a redundant local sense amplifier configured according to an embodiment, may prevent an undesired current loop from forming inside the local sense amplifier. Therefore, the semiconductor having the local sense amplifier according to the embodiment may prevent signal transference between the local I/O lines and the global I/O lines from failing.

The foregoing is illustrative of embodiments of the invention and is not to be construed as limiting thereof. Although example embodiments of this invention have been described, those skilled in the art will readily appreciate that many modifications are possible in the example embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A sense amplifier comprising:
a pair of differential transistors configured to amplify a differential signal applied to a pair of I/O lines, each transistor having a terminal;
a current supplying circuit configured to supply a current to the differential transistors in response to an enable signal; and
a coupling element configured to electrically connect or disconnect the terminals of the differential transistors in response to the enable signal.

2. The sense amplifier of claim 1, wherein the coupling element electrically connects the terminals of the differential transistors when the enable signal is activated, and the coupling element electrically disconnects the terminals of the differential transistors when the enable signal is deactivated.

3. The sense amplifier of claim 1, wherein the coupling element comprises an MOS transistor having a gate responsive to the enable signal.

4. The sense amplifier of claim 1, wherein the current supplying circuit comprises:
a first current supplying unit configured to supply a first current to the terminal of a first one of the differential transistors in response to the enable signal; and
a second current supplying unit configured to supply a second current to the terminal of a second one of the differential transistors in response to the enable signal.

5. The sense amplifier of claim 4, wherein the first and the second current supplying units each comprise:
a plurality of transistors coupled in parallel with each other and responsive to the enable signal, wherein an amount of the associated current is controlled by the number of the plurality of transistors that are turned on in response to the enable signal.

6. The sense amplifier of claim 4, wherein at least one of the first current supplying unit and the second current supplying unit comprises:
a plurality of current supplying transistors coupled between the terminal of the associated differential transistor and a low power source; and
a plurality of switches, each switch configured to enable one of the current supplying transistors in response to the enable signal.

7. The sense amplifier of claim 6, wherein the current supplying transistors are of substantially the same size.

8. The sense amplifier of claim 6, wherein the current supplying transistors are configured to supply currents having weights of a binary code form.

9. The sense amplifier of claim 6, wherein the switches are configured to be fused in desired positions.

10. The sense amplifier of claim 1, wherein the pair of I/O lines is referred to as the pair of local I/O lines, the sense amplifier further comprising:
a first transistor configured to provide a first amplified signal of the amplified differential signal to a first line of a pair of global I/O lines in response to a first control signal;
a second transistor configured to provide a second amplified signal of the amplified differential signal to a second line of the global I/O lines in response to the first control signal;
a third transistor configured to provide a signal on the first line of the global I/O lines to a first line of the local I/O lines in response to a second control signal; and
a fourth transistor configured to provide a signal on the second line of the global I/O lines to a second line of the local I/O lines in response to the second control signal.

11. The sense amplifier of claim 10, wherein:
the first control signal is activated and the second control signal is deactivated for a read operation; and
the first control signal is deactivated and the second control signal is activated for a write operation.

12. A sense amplifier comprising:
a first MOS transistor having a gate coupled to a first I/O line and a source coupled to a first node;
a second MOS transistor having a gate coupled to a second I/O line and a source coupled to a second node;
a third MOS transistor having a source coupled to one side of a power source, a drain coupled to the first node and a gate responsive to an enable signal;
a fourth MOS transistor having a source coupled to the one side of the power source, a drain coupled to the second node and a gate responsive to the enable signal; and
a coupling element configured to electrically connect or disconnect the first node with the second node in response to the enable signal.

13. The sense amplifier of claim 12, wherein the first and second I/O lines are referred to as the first and second local I/O lines, the sense amplifier further comprising:
a fifth MOS transistor configured to provide an output current of the second MOS transistor to a first global I/O line in response to a first control signal;
a sixth MOS transistor configured to provide an output current of the first MOS transistor to a second global I/O line in response to the first control signal;
a seventh MOS transistor configured to provide a signal on the first global I/O line to the first local I/O line in response to a second control signal; and
an eighth MOS transistor configured to provide a signal on the second global I/O line to the second local I/O line in response to the second control signal.

14. The sense amplifier of claim 12, wherein the coupling element comprises an MOS transistor responsive to the enable signal.

15. A semiconductor memory device comprising:
a main circuit including a pair of local I/O lines, a pair of global I/O lines and a local sense amplifier coupled between the local I/O lines and the global I/O lines; and
a redundant circuit including a pair of redundant local I/O lines, a pair of redundant global I/O lines electrically coupled to the global I/O lines, and a redundant local sense amplifier coupled between the redundant local I/O lines and the redundant global I/O lines;
wherein at least one of the local sense amplifier and the redundant local sense amplifier includes:
a pair of differential transistors configured to amplify a differential signal applied to the associated local I/O lines and to provide the amplified differential signal to the associated global I/O lines, each transistor having a terminal;
a current supplying circuit configured to supply a current to the differential transistors in response to an associated enable signal; and
a coupling element configured to electrically connect or disconnect the terminals of the differential transistors in response to the associated enable signal.

16. The semiconductor memory device of claim 15, wherein the coupling element electrically connects the terminals of the differential transistors when the associated enable signal is activated, and electrically disconnects the terminals of the differential transistors when the associated enable signal is deactivated.

17. The semiconductor memory device of claim 15, wherein the coupling element comprises an MOS transistor that is activated in response to the associated enable signal.

18. The local sense amplifier of claim 17, wherein the current supplying circuit comprises:
a first current supplying unit configured to supply a first current to the terminal of a first one of the differential transistors in response to the associated enable signal; and
a second current supplying unit configured to supply a second current to the terminal of a second one of the differential transistors in response to the associated enable signal.

19. The local sense amplifier of claim 18, wherein the first and the second current supplying units each comprise:
a plurality of transistors coupled in parallel with each other and responsive to the enable signal, wherein an amount of the associated current is controlled by the number of the plurality of transistors that are turned on in response to the enable signal.
